(19) United States
(12) Patent Application Publication
(10) Pub. No.: US 2025/0225299 A1
(43) Pub. Date: Jul. 10, 2025

(54) Feature Selection Based Water Washing Prediction

(71) Applicant: Saudi Arabian Oil Company, Dhahran (SA)

(72) Inventors: Fatai A. Anifowose, Al-Khobar (SA); Khaled Arouri, Dhahran (SA); Assad Hadi Ghazwani, Muharraq (BH)

(21) Appl. No.: 18/408,221

(22) Filed: Jan. 9, 2024

(51) Int. Cl. G06F 30/28

(52) U.S. Cl. CPC G06F 30/28

(57) ABSTRACT

A computer implemented method that enables feature based estimation of water washing parameters is described. The method includes obtaining light hydrocarbon components from historical data and deriving engineered features from the historical data. The method includes extracting a subset of features from the light hydrocarbon components and engineered features, and training a machine learning model to predict a respective water washing parameter using the extracted subset of features.

### TECHNICAL FIELD

This disclosure relates generally to feature selection based water washing prediction.

### BACKGROUND

Oil and gas fields include areas of accumulation of respective hydrocarbons in reservoirs, trapped by impermeable rock formations as the hydrocarbons rise. Water washing alters geochemical composition and bulk physical properties of oil and gas accumulations. In particular, water washing strips soluble hydrocarbons from oil or gas accumulations via dissolution.

### BRIEF DESCRIPTION OF DRAWINGS

FIGS. 1A and 1B show a feature selection based water washing prediction workflow.

FIG. 2 shows feature engineering using captured light hydrocarbon components and other derivatives of the gas components.

FIG. 3A shows a water washing intensity index.

FIG. 3B shows water washing intensity indicators integrated with a gross depositional environment map.

FIG. 4 is a process flow diagram of a process that enables a feature selection based water washing prediction.

FIG. 5 illustrates hydrocarbon production operations that include both one or more field operations and one or more computational operations, which exchange information and control exploration for the production of hydrocarbons.

FIG. 6 is a schematic illustration of an example controller (or control system) for that enables feature selection based water washing prediction.

### DETAILED DESCRIPTION

Water washing alters oil and gas accumulations by affecting hydrocarbon types in the accumulations. For example, light alkanes, aromatic hydrocarbons, and other non-hydrocarbons are removed from oil and gas accumulations through contact with moving formation waters in reservoirs, during migration, reservoir storage, or during production. Soluble compounds are removed from the oil and gas accumulations by direct connection of a hydrocarbon reservoir to water. In examples, water washing causes spatial variations in fluid composition within the reservoir, leading to a mismatch between the gas-oil ratio (GOR) and American Petroleum Institute (API) gravity (low GOR accompanied by high API gravity).

Some water washing parameters can be determined from direct lab measurements of heptane (C7) in light hydrocarbon analysis of oil samples. A C7 oil transformation star diagram is created using specialized equipment, such as gas chromatographs, and a geochemistry specialist in a time consuming process. However, water washing parameters can be unavailable when measured in a laboratory setting. For example, water washing parameters are not available for certain wells due to various reasons, such the cost of downhole pressure-volume-temperature (PVT) data or laboratory geochemical measurements.

Embodiments described herein enable feature selection based water washing prediction. A trained machine learning model is built using historical data gathered from the offset wells or wells having similar geological settings. After the model has been built, water washing parameters are predicted by using inputs obtained in real time from the subsurface while drilling. The workflow combines feature engineering and feature selection methods in a single instance of predictive task. In examples, feature engineering creates new features from existing features, and feature selection extracts a subset of features from the original set of features.

In some embodiments, new features (e.g., C1/C2, C2/C3, and C1/C3 ratios; C1/(C1+C2+C3), C1²/(C1+C2+C3)², [C1/(C1+C2+C3)]²) are created on-the-fly. This results in six features. A feature selection algorithm is applied to the acquired and generated features to select a subset of the features that are most significant in the modeling of the water washing parameters (Tr1, GOR, and PDRT) sequentially. The selected subset of features is then used to train a machine learning model to predict water washing parameters. Lastly, the trained machine learning models are used to predict the respective water washing parameters at the rig site. While drilling proceeds at the rig site, light gas components (C1, C2, and C3) acquired in real time are analyzed using the trained machine learning model.

Some advantages of the present techniques include an improvement to water washing by selecting features that have a significant impact on water washing parameters. The selected features are significant as they are the most relevant for modeling the respective water washing parameters in terms of correlation (linear or nonlinear), which ensures higher accuracy. Additionally, using the selected features reduces the dimensionality of the input feature space. This ensures faster modeling, simpler workflow, and more explainable outcome. Using the selected features also reduces the overhead logistics involved in collecting the data required for the model implementation.

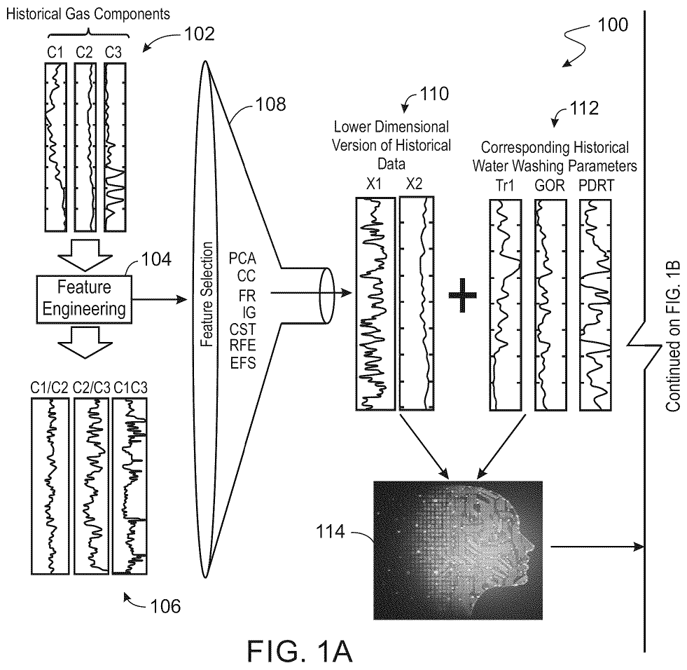

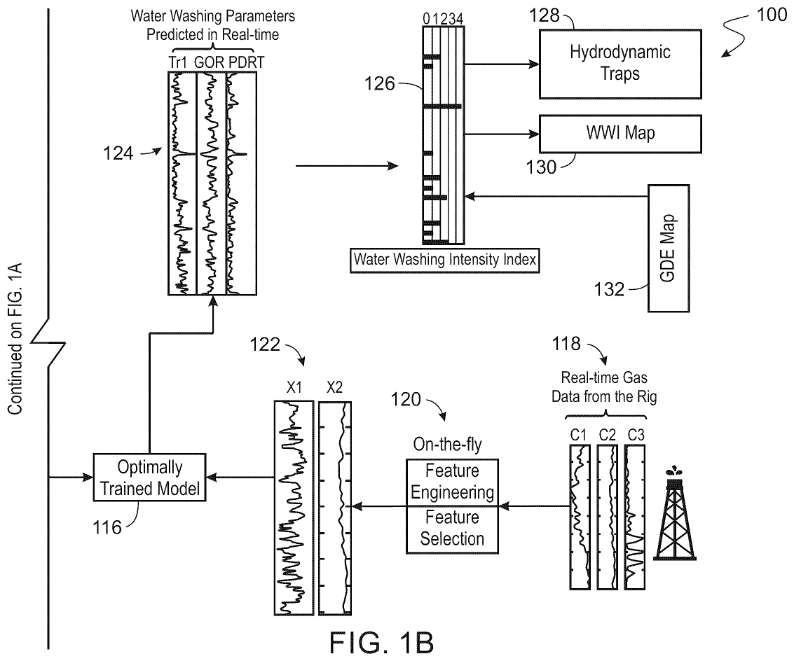

FIGS. 1A and 1B shows a feature selection based water washing prediction workflow 100. At block 102, light hydrocarbon gas components (C1, C2, and C3) are collected from existing (offset) wells. At block 104, leveraging the feature engineering principle of machine learning, at least one ratio and other derivatives of the gas components (e.g., C1/C2, C2/C3, and C1/C3; C1/(C1+C2+C3), C1²/(C1+C2+C3)², [C1/(C1+C2+C3)]²) are calculated. The output of the feature engineering (e.g., derivatives) is shown at block 106. In some embodiments, the features output by the feature engineering at block 104 are the most significant subset of features from the original historical gas components data. In examples, engineered features are created from the acquired light hydrocarbon gas components C1, C2, and C3 collected from existing offset wells. Formulations for engineered features (e.g., ratios) are known but the engineered features are not part of the original set of light hydrocarbon gas components (C1, C2, and C3). The ratios are not produced directly from the data acquisition devices. After acquiring the original set of light hydrocarbon gas components, ratios are calculated. In examples, the engineered features include other different mathematical combinations of the original set of light hydrocarbon gas components. For example, other engineered features include, but are not limited to, C1/(C1+C2+C3), C1²/(C1+C2+C3)², [C1/(C1+C2+C3)]², etc. In some embodiments, engineered features are associated with patterns in training data, and are used to train a machine learning model that predicts a respective water washing parameter. The additional patterns in the training data are learned by the machine learning model during training. In the manner, feature engineering increases the predictive capability of the trained machine learning model.

At block 108, a feature selection module extracts a subset of features from the original set of features from block 102 and engineered features from block 104. The subsets could be selected from the same set of real-time light gas components and the engineered features or may be completely new set of features different from the set of real-time light gas components to generate training data. In examples, the subset of features is extracted based on a linear correlation approach. For example, assume that after estimating a linear correlation between each feature, the following values are obtained: C1=0.75, C2=0.24, C3=0.22, C1/C2=0.45, C2/C3=0.88, and C1/C3=0.66. Using a top-down ranking (e.g., highest linear correlation to lowest linear correlation), the features are ordered as follows: C2/C3, C1, C1/C3, C1/C2, C2, and C3. In some embodiments, feature selection extracts a predetermined number of features. Continuing with the previous example, the top two, three or four features are extracted for use of the entire original features and engineered features. In some embodiments, a cut-off on the linear correlation values is implemented, where those features with a linear correlation greater than a predetermined value are extracted. In examples, the predetermined value is 0.6, which results in extracting C1, C2/C3, and C1/C3 for inclusion in the subset of features.

In examples, the gas components determined at block 102 and the derivatives at block 106 input to the feature selection at block 108. In feature selection, automatic and real-time feature selection could be any of principal component analysis (PCA), correlation coefficient (CC), fuzzy ranking (FR), information gain (IG), Chi square test (CST), Fisher's score (FS1), forward selection (FS2), backward elimination (BE), forward selection with backward elimination (FSBE), and exhaustive feature search (EFS).

The extracted subset of features resulting from feature selection at block 108 are represented by a subset of features X1 and X2 at block 110 of FIG. 1A. In some embodiments, the extracted set of features are lower dimensional versions of historical data. In examples, the subset of features at block 110 could be any of the original set of features, engineered features, or features extracted according to feature selection. For example, using PCA for feature selection would not select any of the existing features (e.g., original set of features or engineered features) but rather would create features that statistically explain the original set of features or engineered features.

The subset of features are represented at block 110. In examples, the subset of features are properties generated from the historical data and used as input to machine learning models. Feature significance indicates how much each feature contributes to the model prediction. Feature significance is a degree of usefulness of a specific feature for a current model and prediction. In some embodiments, feature significance is determined using correlation criteria that quantifies the relationship between the respective feature and at least one of the water washing parameters. In examples, a correlation between a respective feature and each the water washing parameter. Features with a higher absolute value of a correlation coefficient are more significant. The feature selection process is conducted between each feature and each water washing parameter separately. In examples, no averaging is used in feature selection. The selected features for each of the water washing parameters may be different. Accordingly, in examples each water washing parameter has an independent model used to predict the respective water washing parameter.

At block 112, water washing parameters as measured in a laboratory corresponding to the features are obtained. The input features at block 110 are combined with their corresponding water washing parameters measured in the lab at block 112 while ensuring depth-wise alignment. The most significant subset of features from the original historical gas components data and their derivatives are then integrated with their corresponding historical water washing parameters (Toluene/1,1-dimethylcyclopentane (Tr1), gas-oil ratio (GOR), and present-day reservoir temperature (PDRT)). This forms a training database at block 114. In some examples, the resultant training data will be determined by the result of the feature selection process. For example, assume there are 1000 data points. The original 6×1000 data matrix could become 2×1000 after the feature selection process.

Feature selection methods are applied to the integrated training database, and used to create a trained machine learning model. In some embodiments, the trained machine learning model is based on, for example, neural networks, support vector machines, decision trees, random forests, XGBoost, and the like. The trained machine learning model predicts a respective water washing parameter at the rig for a new well being drilled without the need for the traditional extensive laboratory measurements.

The trained machine learning models are lightweight and can execute on devices with limited computing resources. The real-time, automatic, and on-the-fly feature selection used to obtain the most significant input features results in a light-weight model. By using a subset of the initial input feature space, the computational complexity of the models are reduced and the accuracy of the prediction output by the trained models are increased through the use of the most significant input features.

The trained machine learning models are deployed for use in edge computing, where computing is performed at or near the source of data in order to reduce latency and consumed bandwidth. Oil and gas facilities produce large amounts of data. In examples, a single oil rig can generate over a terabyte of data each day. Traditionally this data is not accessed in real time, and is instead transmitted to a remote data center, where traditional applications are hosted and data stored. Depending on the networks available for data transmission, it can take multiple days for a single day's worth of data to be transmitted from an oil rig to the remote data center. By the time transmission is complete, the data may no longer be relevant. The present techniques enable analysis of the data using trained machine learning models at or near the point of data capture (e.g., at the rig site). In some embodiments, the trained machine learning models execute from local devices including internet of things (IoT) devices, industrial internet of things (IIoT) devices, local edge servers and the like. In some embodiments, the trained machine learning model executes from local microcontroller units (MCUs), single board computers, or System on a Chip (SoCs) at or near the point of data capture.

Referring again to FIGS. 1A and 1B, the trained machine learning models at block 116 execute at a rig site. Real time gas data including light hydrocarbon components C1, C2, and C3 are input to a two stage model at block 119. The two stage model at block 119 includes feature engineering and selection at block 120 and the trained machine learning models 116. The light hydrocarbon components from a mud logging system at the rig site are input to feature engineering and selection at block 120 to extract the most significant subset of features 122 from the real time gas data. The most significant features at block 122 are input to trained machine learning models at block 116. The trained machine learning models at block 116 predict the water washing parameters (Tr1, GOR, and PDRT) for the new well being drilled in real time as shown at block 124. In examples, a first trained machine learning model 116 predicts Tr1, a second trained machine learning model 116 predicts GOR, and a third trained machine learning model 116 predicts PDRT.

The predicted values at block 124 are integrated with a gross depositional environment (GDE) map to create a waster washing intensity index at block 126, hydrodynamic traps map at block 128, and water washing index map at block 130, in real time. As shown in FIGS. 1A and 1B, the predicted water washing parameters are used to generate a water washing intensity index (WWII), which when integrated with gross depositional environment (GDE) maps can be used to generate water washing intensity maps and identify potential hydrodynamic traps in real time. In some embodiments, real-time or on the-fly indicates that the described techniques are not implemented separately and are integrated with the entire machine learning workflow. There is no interruption in the modeling process, and to the user it appears that a single process is executing. The feature selection executes quickly to extract a subset of features before moving on to the modeling part of the workflow.

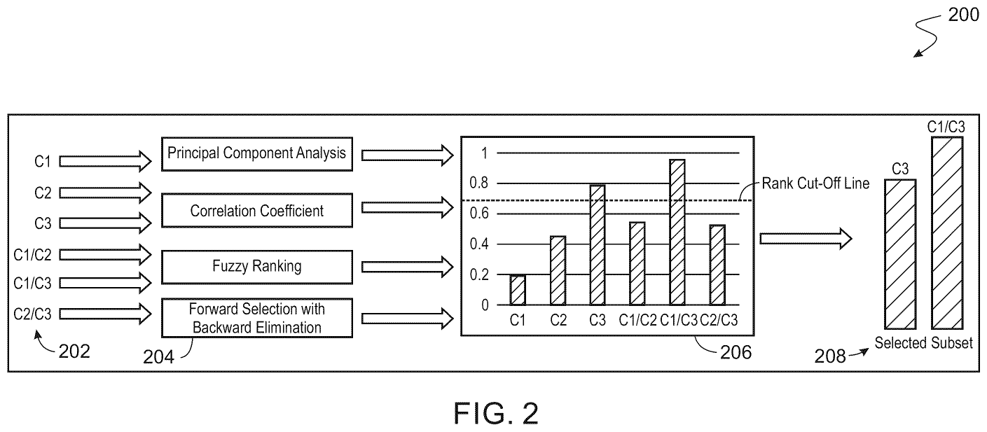

FIG. 2 shows feature engineering using captured light hydrocarbon components and other derivatives of the gas components. Inputs 202 include light hydrocarbon components and other derivatives of the gas components. Feature selection algorithms are shown at block 204. Graph 206 is used to rank the original set of features and engineered features. The graph 206 is shown for exemplary purposes and can be different for each of the feature selection algorithms shown at block 204. For example, PCA creates a subset of features with different degrees of statistical explanation. The features created by PCA are principal components (PCs). The feature with the strongest correlation is PC1, then PC2, PC3, etc. The PCs are ranking as depicted in the graph 206, where a subset of features (e.g., principal components) are extracted. In examples, feature selection using other feature selection algorithms such as fuzzy ranking gives a ranking of the features based on their degree of fuzziness with relation to the respective water washing parameter being modeled. A predetermined cut-off is applied to the ranked features to extract a subset of features that a used to train a model to predict a respective water washing feature.

The extracted subset of features 208 represents the most significant input features to predict water washing parameters instead of the whole set of the real-time light gas components (C1, C2, and C3) and their engineered derivative features (C1/C2, C2/C3, and C1/C3) using the machine learning methodology. This workflow, based on real-time or on-the-fly feature selection, ensures that the subsequent ML model is simple, explainable, more accurate, and light-weight enough to be used on the rig using the edge computing technology.

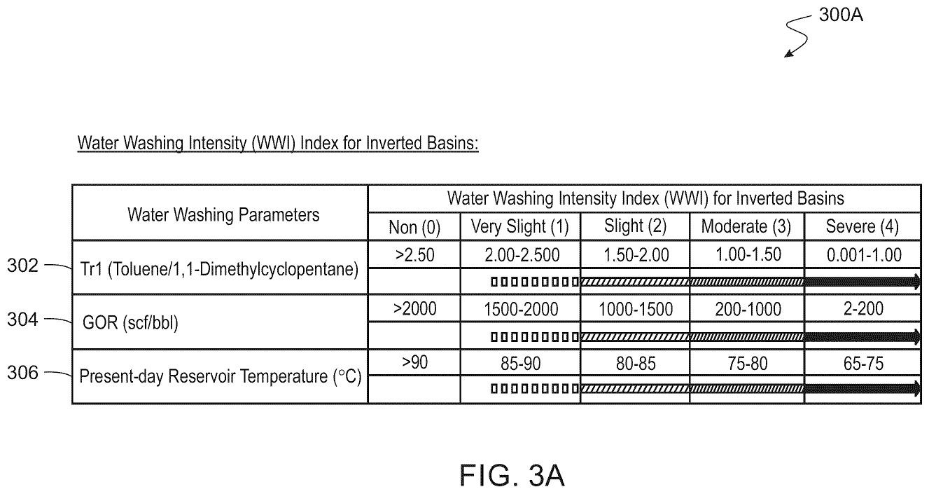

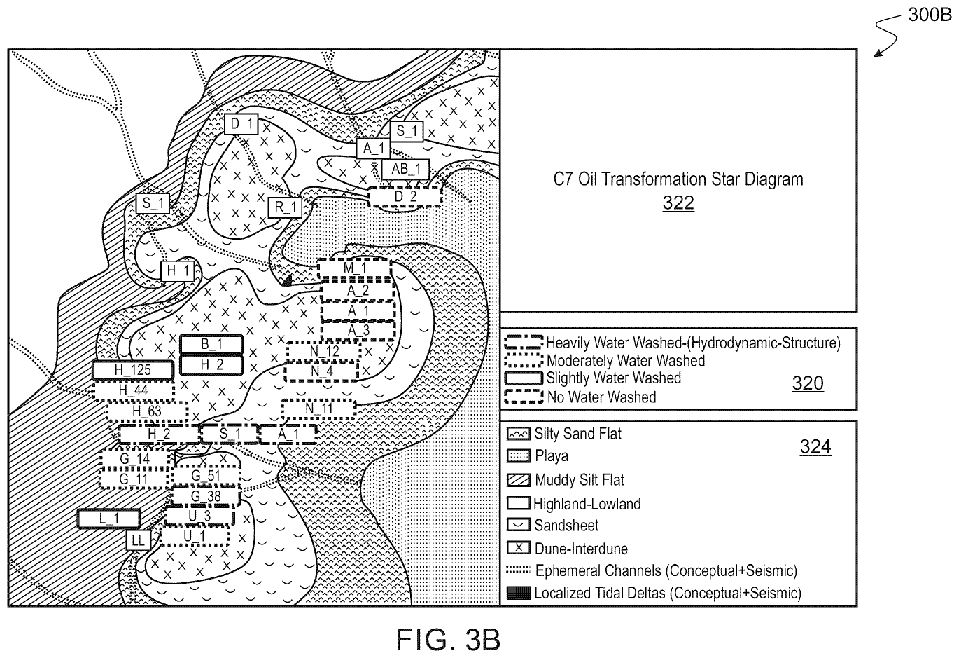

The complete set of estimated water washing parameters (GOR, Tr1 and PDRT) is used to create a water washing intensity index. The index 300A is shown in FIG. 3A, ranging from 0) (none) to 4 (severe). As shown in FIG. 3A, for parameter Tr1 at reference number 302, greater than 2.50 indicates no water washing (index of 0): 2.00-2.50 indicates very slight water washing (index of 1): 1.50-2.00 indicates slight water washing (index of 2): 1.00-1.50 indicates moderate water washing (index of 3); and 0.001-1.00 indicates severe water washing (index of 4). For parameter GOR at reference number 304, greater than 2000 indicates no water washing (index of 0); 1500-2000 indicates very slight water washing (index of 1): 100-1500 indicates slight water washing (index of 2): 200-1000 indicates moderate water washing (index of 3); and 2-200 indicates severe water washing (index of 4). For parameter PDRT at reference number 306, greater than 90 indicates no water washing (index of 0): 85-90 indicates very slight water washing (index of 1): 80-85 indicates slight water washing (index of 2): 75-80 indicates moderate water washing (index of 3); and 65-75 indicates severe water washing (index of 4).

FIG. 3B shows how the water washing intensity indicators are integrated with a GDE map 300B to identify potential hydrodynamic traps. In examples, the water washing intensity index in the legend at reference number 320 is integrated with GDE maps to predict the potential hydrodynamic traps. A C7 oil transformation star diagram is provided at reference number 322, including Tr1, Tr2, Tr3, Tr4, Tr5, Tr6, Tr7, and Tr8. A legend at reference number 324 indicates formation types, including silty sand flat, playa, muddy silt flat, highland-lowland, sandsheet, dune-interdune, ephemeral channels (conceptual and seismic), and localized tidal deltas (conceptual and seismic).

In examples, the water washing intensity index in the legend at reference number 320 corresponds to the index 300A of FIG. 3A. For example, the water washing intensity index in the legend at reference number 320 is based on criteria as provided in the index 300A of FIG. 3A, including the set of original and estimated water washing parameters. As shown in FIG. 3B, the legend at reference number 320 indicates heavily water washed (hydrodynamic structure), moderately water washed, slightly water washed, and no water washed. Integration between the water washing geochemical indicator Tr1 and GDE map in FIG. 3B shows variable reservoir facies. The silty sand sheet is most susceptible to water washing as indicated by water washing indicators Tr1 and may therefore potentially contain hydrodynamically trapped accumulations.

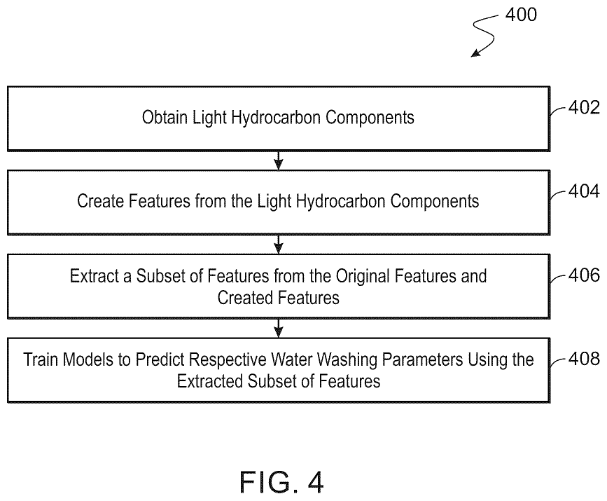

FIG. 4 is a process flow diagram of a process 400 that enables feature selection based water washing prediction. Water washing occurs when the most soluble compounds such as light aromatics and alkanes are removed from the oil by direct connection to meteoric formation water. Water washing has been poorly quantified, and causes spatial variations in fluid composition within the reservoir, leading to a mismatch between the Gas-Oil ratio (GOR) and API gravity (Low GOR and High API gravity). The present techniques fuse a feature selection module into the water washing estimation workflow to perform the automatic feature selection before applying the ML models on the input data.

At block 402, C1, C2 and C3 light hydrocarbon components are obtained from historical data. In examples, the C1, C2 and C3 light hydrocarbon components are collected at multiple depths during drilling. In examples, the light hydrocarbon components obtained by drawing rock samples at each depth and then analyzing the samples.

At block 404, features are generated from the light hydrocarbon components and engineered derivatives by evaluating the historical data to determine the most significant features. In some examples, feature engineering is performed on the historical data to derive new features. For example, using a feature selection method such as PCA, completely new set of features will be created. Out of the six original and engineered features, PCA could recommend only two with the highest principal components. The two PCs will be completely different from the original features.

At block 406, features are extracted from the original set of features and the created (e.g., engineered features). In examples, the original set of features and the engineered features are ranked according to the most significant created features and C1, C2, and C3 gas compositions. The resulting most significant created features and C1, C2, and C3 gas compositions are used to form a training database.

At block 406, a model is trained to predict the WW parameters (Tr1, GOR, and PDRT) using the training database. The model predicts the occurrence of water washing in hydrocarbon reservoirs in real time, and is a light-weight model that can be used on the rig. The water washing parameters Tr1, GOR, and PDRT are predicted in real-time. Additionally, water washing intensity and its effect on reservoir fluids in real time is predicted in real time. Further, water washing intensity maps and potential hydrodynamic traps are predicted in real time.

In examples, using the predicted GOR, PDRT, and Tr1, a water washing intensity index is created. In examples, the water washing parameters and water washing intensity index determined for each depth at which the C1, C2 and C3 gas compositions are determined.

In examples, the water washing intensity index is integrated with a gross depositional environment (GDE) map showing variable reservoir facies. In examples, the water washing intensity index is selected based on the interaction of the main parameters that are highly affected by water washing such as TRI, GOR, PDRT. As described above, in FIG. 3A, the relationship between these parameters are shown, where at certain values of these parameters water washing can be classified as non, very slight, slight, moderate and severe.

In examples, the GDE map is created at a regional scale (tens or hundreds of kilometers scale). The GDE map is focused specifically on the environments that deposited the rocks at the time period being considering. Example polygons on a GDE map could be any depositional environment, including fluvial channels, deepwater slope channels, lake margin carbonates, salt-water marsh shales, etc. In examples, integrating the water washing intensity index with the GDE map provides additional polygons on the GDE map that indicates the water washing intensity index associated with oil accumulations. In examples, the integrated map is rendered on a display device, such as a computer screen.

In some embodiments, potential hydrodynamic traps are predicted. In examples, a pathway to inject CO2 into the subsurface is derived based on the predicted hydrodynamic traps. When there is a strong hydrodynamic flow, hydrocarbons are flushed away from the trap. The remaining is water where hydrodynamic traps have low reservoir temperatures and can be used for CO2 storage because the CO2 solubility increases in water at low temperatures. Additionally, in examples, the location of one or more hydrodynamic traps are predicted using the GDE map. Formation fluid pressure data are used for mapping prospective hydrodynamic traps. Combining formation fluid pressures with other data, such as density and subsea elevation, produces maps that help outline areas where hydrodynamic gradients may have created, destroyed, or modified traps.

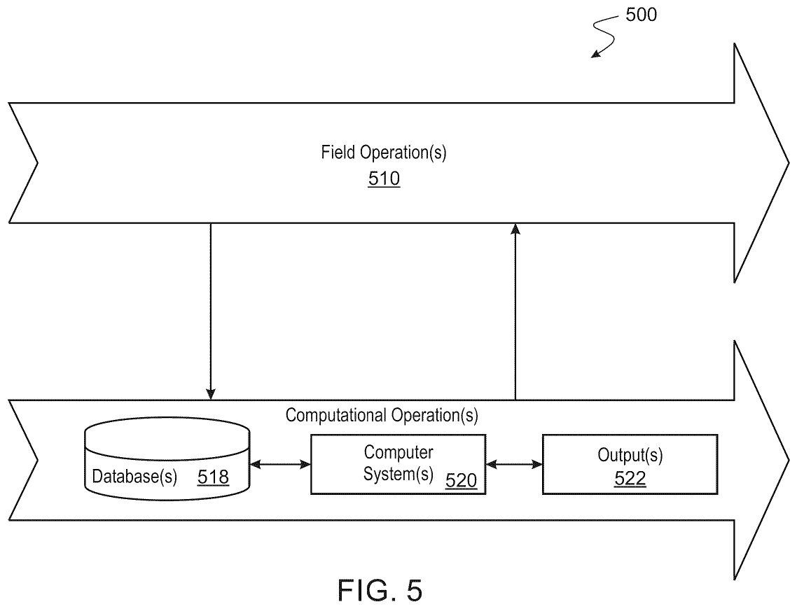

FIG. 5 illustrates hydrocarbon production operations 500 that include both one or more field operations 510 and one or more computational operations 512, which exchange information and control exploration for the production of hydrocarbons. In some implementations, outputs of techniques of the present disclosure can be performed before, during, or in combination with the hydrocarbon production operations 500, specifically, for example, either as field operations 510 or computational operations 512, or both.

Examples of field operations 510 include forming/drilling a wellbore, hydraulic fracturing, producing through the wellbore, injecting fluids (such as water) through the wellbore, to name a few. In some implementations, methods of the present disclosure can trigger or control the field operations 510. For example, the methods of the present disclosure can generate data from hardware/software including sensors and physical data gathering equipment (e.g., seismic sensors, well logging tools, flow meters, and temperature and pressure sensors). The methods of the present disclosure can include transmitting the data from the hardware/software to the field operations 510 and responsively triggering the field operations 510 including, for example, generating plans and signals that provide feedback to and control physical components of the field operations 510. Alternatively or in addition, the field operations 510 can trigger the methods of the present disclosure. For example, implementing physical components (including, for example, hardware, such as sensors) deployed in the field operations 510 can generate plans and signals that can be provided as input or feedback (or both) to the methods of the present disclosure.

Examples of computational operations 512 include one or more computer systems 520 that include one or more processors and computer-readable media (e.g., non-transitory computer-readable media) operatively coupled to the one or more processors to execute computer operations to perform the methods of the present disclosure. The computational operations 512 can be implemented using one or more databases 518, which store data received from the field operations 510 and/or generated internally within the computational operations 512 (e.g., by implementing the methods of the present disclosure) or both. For example, the one or more computer systems 520 process inputs from the field operations 510 to assess conditions in the physical world, the outputs of which are stored in the databases 518. For example, seismic sensors of the field operations 510 can be used to perform a seismic survey to map subterranean features, such as facies and faults. In performing a seismic survey, seismic sources (e.g., seismic vibrators or explosions) generate seismic waves that propagate in the earth and seismic receivers (e.g., geophones) measure reflections generated as the seismic waves interact with boundaries between layers of a subsurface formation. The source and received signals are provided to the computational operations 512 where they are stored in the databases 518 and analyzed by the one or more computer systems 520.

In some implementations, one or more outputs 522 generated by the one or more computer systems 520 can be provided as feedback/input to the field operations 510 (either as direct input or stored in the databases 518). The field operations 510 can use the feedback/input to control physical components used to perform the field operations 510 in the real world.

For example, the computational operations 512 can process the seismic data to generate three-dimensional (3D) maps of the subsurface formation. The computational operations 512 can use these 3D maps to provide plans for locating and drilling exploratory wells. In some operations, the exploratory wells are drilled using logging-while-drilling (LWD) techniques which incorporate logging tools into the drill string. LWD techniques can enable the computational operations 512 to process new information about the formation and control the drilling to adjust to the observed conditions in real-time.

The one or more computer systems 520 can update the 3D maps of the subsurface formation as information from one exploration well is received and the computational operations 512 can adjust the location of the next exploration well based on the updated 3D maps. Similarly, the data received from production operations can be used by the computational operations 512 to control components of the production operations. For example, production well and pipeline data can be analyzed to predict slugging in pipelines leading to a refinery and the computational operations 512 can control machine operated valves upstream of the refinery to reduce the likelihood of plant disruptions that run the risk of taking the plant offline.

In some implementations of the computational operations 512, customized user interfaces can present intermediate or final results of the above-described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or app), or at a central processing facility.

The presented information can include feedback, such as changes in parameters or processing inputs, that the user can select to improve a production environment, such as in the exploration, production, and/or testing of petrochemical processes or facilities. For example, the feedback can include parameters that, when selected by the user, can cause a change to, or an improvement in, drilling parameters (including drill bit speed and direction) or overall production of a gas or oil well. The feedback, when implemented by the user, can improve the speed and accuracy of calculations, streamline processes, improve models, and solve problems related to efficiency, performance, safety, reliability, costs, downtime, and the need for human interaction.

In some implementations, the feedback can be implemented in real-time, such as to provide an immediate or near-immediate change in operations or in a model. The term real-time (or similar terms as understood by one of ordinary skill in the art) means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

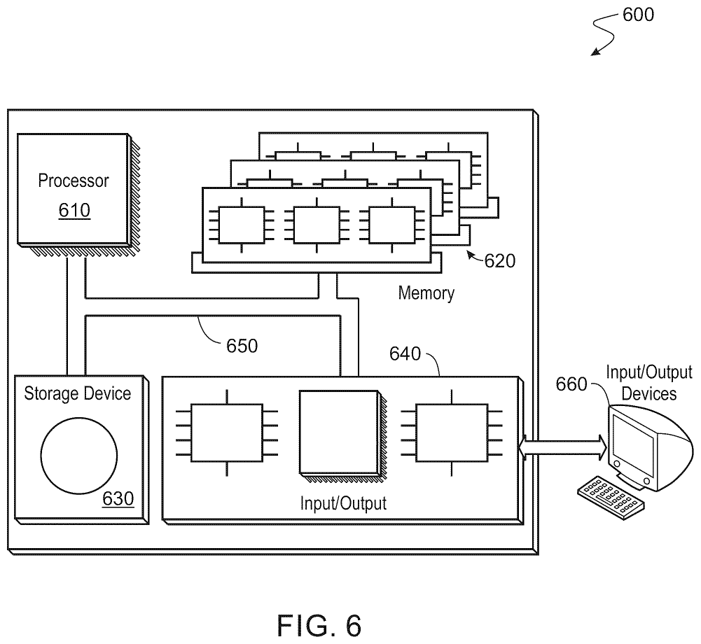

FIG. 6 is a schematic illustration of an example controller 600 (or control system) for that enables feature selection based water washing prediction. For example, the controller 600 may be operable according to the workflow 100 of FIGS. 1A and 1B or the process 400 of FIG. 4. In some embodiments, the controller 600 is the same as or similar to the computer systems 520 of FIG. 5. The controller 600 is intended to include various forms of digital computers, such as printed circuit boards (PCB), processors, digital circuitry, or otherwise parts of a system for supply chain alert management. Additionally the system can include portable storage media, such as, Universal Serial Bus (USB) flash drives. For example, the USB flash drives may store operating systems and other applications. The USB flash drives can include input/output components, such as a wireless transmitter or USB connector that may be inserted into a USB port of another computing device.

The controller 600 includes a processor 610, a memory 620, a storage device 630, and an input/output interface 640 communicatively coupled with input/output devices 660 (for example, displays, keyboards, measurement devices, sensors, valves, pumps). Each of the components 610, 620, 630, and 640 are interconnected using a system bus 650. The processor 610 is capable of processing instructions for execution within the controller 600. The processor may be designed using any of a number of architectures. For example, the processor 610 may be a CISC (Complex Instruction Set Computers) processor, a RISC (Reduced Instruction Set Computer) processor, or a MISC (Minimal Instruction Set Computer) processor.

In one implementation, the processor 610 is a single-threaded processor. In another implementation, the processor 610 is a multi-threaded processor. The processor 610 is capable of processing instructions stored in the memory 620 or on the storage device 630 to display graphical information for a user interface on the input/output interface 640.

The memory 620 stores information within the controller 600. In one implementation, the memory 620 is a computer-readable medium. In one implementation, the memory 620 is a volatile memory unit. In another implementation, the memory 620 is a nonvolatile memory unit.

The storage device 630 is capable of providing mass storage for the controller 600. In one implementation, the storage device 630 is a computer-readable medium. In various different implementations, the storage device 630 may be a floppy disk device, a hard disk device, an optical disk device, or a tape device.

The input/output interface 640 provides input/output operations for the controller 600. In one implementation, the input/output devices 660 includes a keyboard and/or pointing device. In another implementation, the input/output devices 660 includes a display unit for displaying graphical user interfaces.

There can be any number of controllers 600 associated with, or external to, a computer system containing controller 600, with each controller 600 communicating over a network. Further, the terms “client,” “user,” and other appropriate terminology can be used interchangeably, as appropriate, without departing from the scope of the present disclosure. Moreover, the present disclosure contemplates that many users can use one controller 600 and one user can use multiple controllers 600.

### EMBODIMENTS/EXAMPLES

According to some non-limiting embodiments or examples, provided is a computer-implemented method for estimating water washing parameters, the method including: obtaining, using at least one hardware processor, light hydrocarbon components from historical data: deriving, using the at least one hardware processor, engineered features from the historical data, wherein the engineered features are created based on patterns found in the historical data: extracting, using the at least one hardware processor, a subset of features from the light hydrocarbon components and engineered features; and training, using the at least one hardware processor, a machine learning model to predict a respective water washing parameter using light hydrocarbon components from unseen wells in real time, wherein the machine learning model is trained using the extracted subset of features.

According to some non-limiting embodiments or examples, provided is an apparatus including a non-transitory, computer readable, storage medium that stores instructions that, when executed by at least one processor, cause the at least one processor to perform operations including: obtaining light hydrocarbon components from historical data: deriving engineered features from the historical data, wherein the engineered features are created based on patterns found in the historical data; extracting a subset of features from the light hydrocarbon components and engineered features; and training a machine learning model to predict a respective water washing parameter using light hydrocarbon components from unseen wells in real time, wherein the machine learning model is trained using the extracted subset of features.

According to some non-limiting embodiments or examples, provided is a system, including: one or more memory modules; one or more hardware processors communicably coupled to the one or more memory modules, the one or more hardware processors configured to execute instructions stored on the one or more memory models to perform operations including: obtaining light hydrocarbon components from historical data: deriving engineered features from the historical data, wherein the engineered features are created based on patterns found in the historical data: extracting a subset of features from the light hydrocarbon components and engineered features; and training a machine learning model to predict a respective water washing parameter using light hydrocarbon components from unseen wells in real time, wherein the machine learning model is trained using the extracted subset of features.

Further non-limiting aspects or embodiments are set forth in the following numbered embodiments:

Embodiment 1: A computer-implemented method for estimating water washing parameters, the method including: obtaining, using at least one hardware processor, light hydrocarbon components from historical data: deriving, using the at least one hardware processor, engineered features from the historical data, wherein the engineered features are created based on patterns found in the historical data; extracting, using the at least one hardware processor, a subset of features from the light hydrocarbon components and engineered features; and training, using the at least one hardware processor, a machine learning model to predict a respective water washing parameter using light hydrocarbon components from unseen wells in real time, wherein the machine learning model is trained using the extracted subset of features.

Embodiment 2: The computer implemented method of any preceding embodiment, wherein the subset of features is extracted using a linear correlation between each feature and a respective water washing parameter.

Embodiment 3: The computer implemented method of any preceding embodiment, wherein extracting the subset of features includes ranking the light hydrocarbon components and engineered features and applying a predetermined cutoff of the ranked light hydrocarbon components and engineered features.

Embodiment 4: The computer implemented method of any preceding embodiment, wherein extracting the subset of features includes applying principal component analysis to the light hydrocarbon components and engineered features to obtain the extracted subset of features.

Embodiment 5: The computer implemented method of any preceding embodiment, wherein the trained machine learning model executes locally at a rig site.

Embodiment 6: The computer implemented method of any preceding embodiment, wherein the machine learning model is trained using the extracted subset of features and their corresponding water washing parameters.

Embodiment 7: The computer implemented method of any preceding embodiment, wherein the respective water washing parameter is Toluene/1,1-dimethylcyclopentane (Tr1), gas-oil ratio (GOR), or present-day reservoir temperature (PDRT).

Embodiment 8: An apparatus including a non-transitory, computer readable, storage medium that stores instructions that, when executed by at least one processor, cause the at least one processor to perform operations including: obtaining light hydrocarbon components from historical data: deriving engineered features from the historical data, wherein the engineered features are created based on patterns found in the historical data: extracting a subset of features from the light hydrocarbon components and engineered features; and training a machine learning model to predict a respective water washing parameter using light hydrocarbon components from unseen wells in real time, wherein the machine learning model is trained using the extracted subset of features.

Embodiment 9: The apparatus of any preceding embodiment, wherein the subset of features is extracted using a linear correlation between each feature and a respective water washing parameter.

Embodiment 10: The apparatus of any preceding embodiment, wherein extracting the subset of features includes ranking the light hydrocarbon components and engineered features and applying a predetermined cutoff of the ranked light hydrocarbon components and engineered features.

Embodiment 11: The apparatus of any preceding embodiment, wherein extracting the subset of features includes applying principal component analysis to the light hydrocarbon components and engineered features to obtain the extracted subset of features.

Embodiment 12: The apparatus of any preceding embodiment, wherein the trained machine learning model executes locally at a rig site.

Embodiment 13: The apparatus of any preceding embodiment, wherein the machine learning model is trained using the extracted subset of features and their corresponding water washing parameters.

Embodiment 14: The apparatus of any preceding embodiment, wherein the respective water washing parameter is Toluene/1,1-dimethylcyclopentane (Tr1), gas-oil ratio (GOR), or present-day reservoir temperature (PDRT).

Embodiment 15: A system, including: one or more memory modules; one or more hardware processors communicably coupled to the one or more memory modules, the one or more hardware processors configured to execute instructions stored on the one or more memory models to perform operations including: obtaining light hydrocarbon components from historical data: deriving engineered features from the historical data, wherein the engineered features are created based on patterns found in the historical data: extracting a subset of features from the light hydrocarbon components and engineered features; and training a machine learning model to predict a respective water washing parameter using light hydrocarbon components from unseen wells in real time, wherein the machine learning model is trained using the extracted subset of features.

Embodiment 16: The system of any preceding embodiment, wherein the subset of features is extracted using a linear correlation between each feature and a respective water washing parameter.

Embodiment 17: The system of any preceding embodiment, wherein extracting the subset of features includes ranking the light hydrocarbon components and engineered features and applying a predetermined cutoff of the ranked light hydrocarbon components and engineered features.

Embodiment 18: The system of any preceding embodiment, wherein extracting the subset of features includes applying principal component analysis to the light hydrocarbon components and engineered features to obtain the extracted subset of features.

Embodiment 19: The system of any preceding embodiment, wherein the trained machine learning model executes locally at a rig site.

Embodiment 20: The system of any preceding embodiment, wherein the machine learning model is trained using the extracted subset of features and their corresponding water washing parameters.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. The example, the signal can be a machine-generated electrical, optical, or electromagnetic signal that is generated to encode information for transmission to suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatus, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example, LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory. A computer can also include, or be operatively coupled to, one or more mass storage devices for storing data. In some implementations, a computer can receive data from, and transfer data to, the mass storage devices including, for example, magnetic, magneto optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks. Computer readable media can also include magneto optical disks and optical memory devices and technologies including, for example, digital video disc (DVD), CD ROM, DVD+/−R, DVD-RAM, DVD-ROM, HD-DVD, and BLURAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated in, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a key board and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that is used by the user. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship. Cluster file systems can be any file system type accessible from multiple servers for read and update. Locking or consistency tracking may not be necessary since the locking of exchange file system can be done at application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

Particular embodiments of the subject matter have been described. Other embodiments are within the scope of the following claims. For example, the actions recited in the claims can be performed in a different order and still achieve desirable results. As one example, some processes depicted in the accompanying figures do not necessarily require the particular order shown, or sequential order, to achieve desirable results.

What is claimed is:

1. A computer-implemented method for estimating water washing parameters, the method comprising:
obtaining, using at least one hardware processor, light hydrocarbon components from historical data;
deriving, using the at least one hardware processor, engineered features from the historical data, wherein the engineered features are created based on patterns found in the historical data;
extracting, using the at least one hardware processor, a subset of features from the light hydrocarbon components and engineered features; and
training, using the at least one hardware processor, a machine learning model to predict a respective water washing parameter using light hydrocarbon components from unseen wells in real time, wherein the machine learning model is trained using the extracted subset of features.

2. The computer implemented method of claim 1, wherein the subset of features is extracted using a linear correlation between each feature and a respective water washing parameter.

3. The computer implemented method of claim 1, wherein extracting the subset of features comprises ranking the light hydrocarbon components and engineered features and applying a predetermined cutoff of the ranked light hydrocarbon components and engineered features.

4. The computer implemented method of claim 1, wherein extracting the subset of features comprises applying principal component analysis to the light hydrocarbon components and engineered features to obtain the extracted subset of features.

5. The computer implemented method of claim 1, wherein the trained machine learning model executes locally at a rig site.

6. The computer implemented method of claim 1, wherein the machine learning model is trained using the extracted subset of features and their corresponding water washing parameters.

7. The computer implemented method of claim 1, wherein the respective water washing parameter is Toluene/1,1-dimethylcyclopentane (Tr1), gas-oil ratio (GOR), or present-day reservoir temperature (PDRT).

8. An apparatus comprising a non-transitory, computer readable, storage medium that stores instructions that, when executed by at least one processor, cause the at least one processor to perform operations comprising:
obtaining light hydrocarbon components from historical data;
deriving engineered features from the historical data, wherein the engineered features are created based on patterns found in the historical data;
extracting a subset of features from the light hydrocarbon components and engineered features; and
training a machine learning model to predict a respective water washing parameter using light hydrocarbon components from unseen wells in real time, wherein the machine learning model is trained using the extracted subset of features.

9. The apparatus of claim 8, wherein the subset of features is extracted using a linear correlation between each feature and a respective water washing parameter.

10. The apparatus of claim 8, wherein extracting the subset of features comprises ranking the light hydrocarbon components and engineered features and applying a predetermined cutoff of the ranked light hydrocarbon components and engineered features.

11. The apparatus of claim 8, wherein extracting the subset of features comprises applying principal component analysis to the light hydrocarbon components and engineered features to obtain the extracted subset of features.

12. The apparatus of claim 8, wherein the trained machine learning model executes locally at a rig site.

13. The apparatus of claim 8, wherein the machine learning model is trained using the extracted subset of features and their corresponding water washing parameters.

14. The apparatus of claim 8, wherein the respective water washing parameter is Toluene/1,1-dimethylcyclopentane (Tr1), gas-oil ratio (GOR), or present-day reservoir temperature (PDRT).

15. A system, comprising:
one or more memory modules;
one or more hardware processors communicably coupled to the one or more memory modules, the one or more hardware processors configured to execute instructions stored on the one or more memory models to perform operations comprising:
obtaining light hydrocarbon components from historical data;
deriving engineered features from the historical data, wherein the engineered features are created based on patterns found in the historical data;
extracting a subset of features from the light hydrocarbon components and engineered features; and
training a machine learning model to predict a respective water washing parameter using light hydrocarbon components from unseen wells in real time, wherein the machine learning model is trained using the extracted subset of features.

16. The system of claim 15, wherein the subset of features is extracted using a linear correlation between each feature and a respective water washing parameter.

17. The system of claim 15, wherein extracting the subset of features comprises ranking the light hydrocarbon components and engineered features and applying a predetermined cutoff of the ranked light hydrocarbon components and engineered features.

18. The system of claim 15, wherein extracting the subset of features comprises applying principal component analysis to the light hydrocarbon components and engineered features to obtain the extracted subset of features.

19. The system of claim 15, wherein the trained machine learning model executes locally at a rig site.

20. The system of claim 15, wherein the machine learning model is trained using the extracted subset of features and their corresponding water washing parameters.
